(19) United States
(12) Patent Application Publication
(10) Pub. No.: US 2020/0293736 A1
(43) Pub. Date: Sep. 17, 2020

(54) FINGERPRINT RECOGNIZING DEVICE AND DISPLAY DEVICE

(71) Applicant: BOE Technology Group Co., Ltd., Beijing (CN)

(72) Inventors: Yingming LIU, Beijing (CN); Xiaochuan CHEN, Beijing (CN); Haisheng WANG, Beijing (CN); Xiaoliang DING, Beijing (CN); Lei WANG, Beijing (CN); Lijun ZHAO, Beijing (CN); Xiufeng LI, Beijing (CN); Chenyang ZHANG, Beijing (CN)

(73) Assignee: BOE Technology Group Co., Ltd.

(21) Appl. No.: 16/662,133

(22) Filed: Oct. 24, 2019

(30) Foreign Application Priority Data
Mar. 12, 2019 (CN) 201910183584.3

(51) Int. Cl. G06K 9/00; H01L 41/047; H01L 41/053; H01L 41/113; H01L 27/20; H01L 27/32; G06F 3/041

(52) U.S. Cl. CPC G06K 9/0002; H01L 41/0477; H01L 41/0533; G06F 3/0412; H01L 27/20; H01L 27/323; H01L 41/1132

(57) ABSTRACT

Disclosed are a fingerprint recognizing device and a display device. The fingerprint recognizing device includes a plurality of ultrasonic sensing elements, each of which includes a first electrode, a piezoelectric layer located on one side of the first electrode, and a second electrode located on the side of the piezoelectric layer away from the first electrode, wherein at least one of the first electrode and the second electrode includes a plurality of stacked sub-electrode layers, and two adjacent sub-electrode layers have different sonic impedances.

### CROSS-REFERENCE TO RELATED APPLICATION

This application claims priority of Chinese Patent Application No. 201910183584.3, filed on Mar. 12, 2019, which is hereby incorporated by reference in its entirety.

### FIELD

The present disclosure relates to the field of semiconductor technologies, and particularly to a fingerprint recognizing device and a display device.

### BACKGROUND

As the economies and the sciences and technologies are developing rapidly, consumer electronic products represented by mobile phones have been popularized rapidly, and display modules which are the most important component of the mobile phones are also developing rapidly; and as there is a demand of consumers for higher performance of the display modules, the development of products with an ultra-high screen to panel ratio and even without any bezel will be promising in future.

Fingerprint recognition is required in an all-screen display panel in that a fingerprint can be captured at any position on the display panel, so no hole will be opened on the front face thereof of glass to thereby greatly improve the integrality of a mobile phone in appearance. There are two categories of technologies at present to satisfy this requirement, where one category relates to optical fingerprint recognition, and the other relates to ultrasonic fingerprint recognition.

### SUMMARY

Some embodiments of the disclosure provide a fingerprint recognizing device including a plurality of ultrasonic sensing elements, each of which includes a first electrode, a piezoelectric layer located on one side of the first electrode, and a second electrode located on a side of the piezoelectric layer away from the first electrode, wherein:

at least one of the first electrode and the second electrode includes a plurality of stacked sub-electrode layers, and two adjacent sub-electrode layers have different sonic impedances.

In a possible implementation, the second electrodes include a plurality of stacked sub-electrode layers; and the fingerprint recognizing device further includes a protective layer located on a side of the second electrode away from the piezoelectric layer, the protective layer includes a plurality of stacked sub-protective layers, and two adjacent sub-protective layers have different sonic impedances.

In a possible implementation, materials of the two adjacent sub-protective layers are silicon nitride and resin respectively.

In a possible implementation, materials of the two adjacent sub-electrode layers of the second electrodes are molybdenum and aluminum respectively.

In a possible implementation, the first electrode and the second electrode include a plurality of stacked sub-electrode layers respectively.

In a possible implementation, the first electrode is a receiving electrode, and the second electrode is a transmitting electrode.

In a possible implementation, a plurality of adjacent ultrasonic sensing elements are grouped together, transmitting electrodes of a group of ultrasonic sensing elements are formed as an integral planar electrode, and the transmitting electrodes of different groups of ultrasonic sensing elements are spaced from each other.

Some embodiments of the disclosure further provide a display device including the fingerprint recognizing devices according to the embodiment of the disclosure, and a display module.

In a possible implementation, the fingerprint recognizing devices include an underlying substrate on which the plurality of ultrasonic sensing elements are arranged, the display module and the ultrasonic sensing elements are located on different sides of the underlying substrate, and the display module is fit on the underlying substrate of the fingerprint recognizing devices through an adhesive layer.

In a possible implementation, the fingerprint recognizing devices include an underlying substrate on which the plurality of ultrasonic sensing elements are arranged, the display module and the ultrasonic sensing elements are located on a same side of the underlying substrate, and the ultrasonic sensing elements are located between the display module and the underlying substrate.

In a possible implementation, the first electrodes and the second electrode include a plurality of stacked sub-electrode layers respectively, and a quantity of sub-electrode layers in one of the first electrodes and the second electrodes is greater than a quantity of sub-electrode layers in the other one of the first electrode the second electrode, wherein the one of the first electrode and the second electrode is away from the display module.

In a possible implementation, the display module includes a light-emitting diode device, and an encapsulation cover plate located on the side of the light-emitting diode element away from the ultrasonic sensing elements.

In a possible implementation, the first electrode and the second electrode of the fingerprint recognizing devices are reused as touch electrodes.

### BRIEF DESCRIPTION OF THE DRAWINGS

FIG. 1 is a schematic structural diagram of a fingerprint recognizing device according to some embodiments of the disclosure;

FIG. 2 is a schematic structural diagram of a fingerprint recognizing device according to some embodiments of the disclosure, which includes a first electrode structure in a stack, where a finger is below the fingerprint recognizing device;

FIG. 3 is a schematic structural diagram of a fingerprint recognizing device according to some embodiments of the disclosure, which includes a first electrode structure in a stack, where a finger is below the fingerprint recognizing device;

FIG. 4 is a schematic structural diagram of a fingerprint recognizing device according to some embodiments of the disclosure, which includes a second electrode structure in a stack, where a finger is above the fingerprint recognizing device;

FIG. 5 is a schematic diagram of an ultrasonic signal transmitted at an interface in some embodiments of the disclosure;

FIG. 6 is a schematic structural diagram of another ultrasonic signal transmitted at an interface in some embodiments of the disclosure;

FIG. 7 is a schematic diagram of a protective layer structured in a stack in some embodiments of the disclosure;

FIG. 8 is a schematic structural diagram of a first electrode and a second electrode, both of which are structured in a stack in some embodiments of the disclosure;

FIG. 9 is a schematic structural diagram of a display device according to some embodiments of the disclosure;

FIG. 10 is a schematic structural diagram of another display device according to some embodiments of the disclosure;

FIG. 11 is a schematic structural diagram of a particular display device according to some embodiments of the disclosure; and

FIG. 12 is a schematic flow chart of fabricating a display device according to some embodiments of the disclosure.

### DETAILED DESCRIPTION OF THE EMBODIMENTS

In order to make the objects, technical solutions, and advantages of the embodiments of the disclosure more apparent, the technical solutions according to the embodiments of the disclosure will be described below clearly and fully with reference to the drawings in the embodiments of the disclosure. Apparently the embodiments to be described are only a part but not all of the embodiments of the disclosure. Based upon the embodiments here of the disclosure, all the other embodiments which can occur to those ordinarily skilled in the art without any inventive effort shall come into the scope of the disclosure as claimed.

Unless defined otherwise, technical terms or scientific terms throughout the disclosure shall convey their usual meaning as appreciated by those ordinarily skilled in the art to which the disclosure pertains. The terms “first”, “second”, or the like throughout the disclosure do not suggest any order, number or significance, but is only intended to distinguish different components from each other. Alike the terms “include”, “comprise”, or the like refer to that an element or an item preceding to the term encompasses an element(s) or an item(s) succeeding to the term, and its (or their) equivalence(s), but shall not preclude another element(s) or item(s). The term “connect”, “connected”, or the like does not suggest physical or mechanical connection, but may include electrical connection no matter whether it is direct or indirect. The terms “above”, “below”, “left”, “right”, etc., are only intended to represent a relative positional relationship, and when the absolute position of an object as described is changed, the relative positional relationship may also be changed accordingly.

In order to for a clear and concise description below of the embodiments of the disclosure, a detailed description of known functions and components will be omitted in the description.

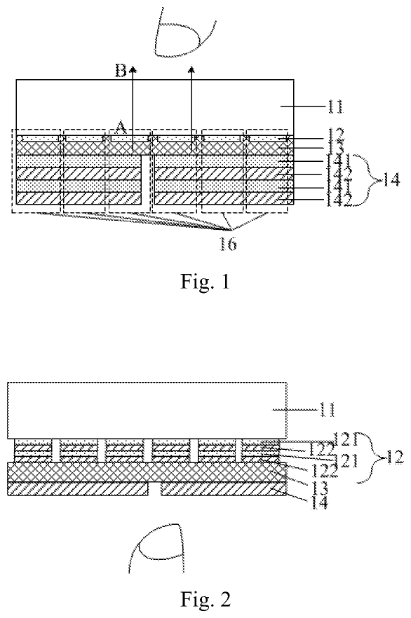

As illustrated in FIG. 1, some embodiments of the disclosure provide a fingerprint recognizing device including a plurality of ultrasonic sensing elements 16, each of which includes a first electrode 12, a piezoelectric layer 13 located on one side of the first electrode 12, and a second electrode 14 located on the side of the piezoelectric layer 13 away from the first electrode 12, where at least one of the first electrode 12 and the second electrode 14 includes a plurality of stacked sub-electrode layers, and there are different sonic impedances of two adjacent sub-electrode layers; and optionally, for example, one of the electrodes, which is arranged behind in the direction in which an ultrasonic signal is transmitted to a finger is transmitted, includes a plurality of stacked sub-electrode layers, and there are different sonic impedances of two adjacent sub-electrode layers. As illustrated in FIG. 2, the direction in which the ultrasonic signal is transmitted to the finger is transmitted is represented by the arrow AB, and the second electrode 14 is the electrode arranged behind, so the second electrode 14 is structured as a plurality of stacked sub-electrode layers, and includes a first sub-electrode layer 141 and a second sub-electrode layer 142 arranged successively, and there are different sonic impedances of the sub-electrode layer 141 and the second sub-electrode layer 142.

The fingerprint recognizing device according to the embodiment of the disclosure includes a plurality of ultrasonic sensing elements located on one side of an underlying substrate, each of which includes a first electrode, a piezoelectric layer located on the side of the first electrode away from the underlying substrate, and a second electrode located on the side of the piezoelectric layer away from the first electrode, where at least one of the first electrode and the second electrode includes a plurality of stacked sub-electrode layers, and there are different sonic impedances of two adjacent sub-electrode layers, that is, the first electrode or the second electrode sorted behind is structured as a plurality of stacked sub-electrode layers, and since there are different sonic impedances of two adjacent sub-electrode layers, and an ultrasonic signal is reflected between interfaces of the two layers with different sonic impedances, the plurality of stacked layers with different sonic impedances can reflect the generated ultrasonic signal to the finger side to thereby improve the intensity of the emitted ultrasonic signal so as to detect a fingerprint, thus avoiding such a problem that when a patterned ultrasonic reflecting electrode layer with a large thickness is formed in a screen-printing process, the pattern may be less refined, and when the ultrasonic reflecting layer is formed in a photolithograph process, a demand for ultrasonic reflection may be difficult to satisfy due to the thickness of the ultrasonic reflecting layer.

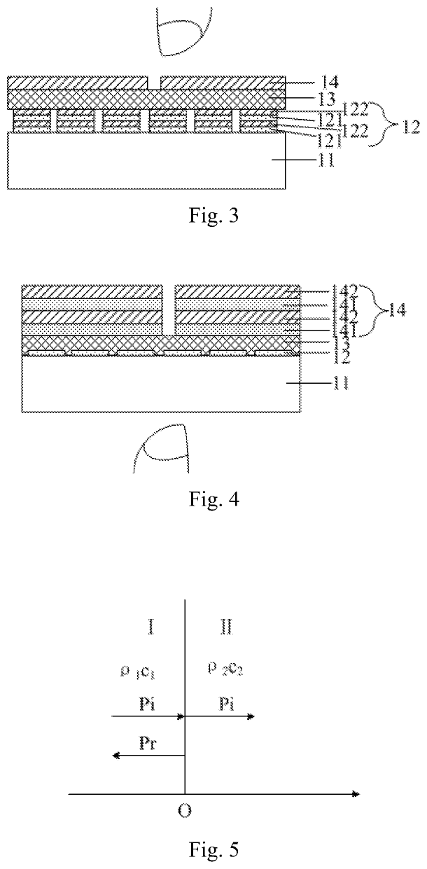

In a particular implementation, each ultrasonic sensing element 16 can be arranged below the underlying substrate as illustrated in FIG. 1, where the first electrode 2, the piezoelectric layer 13, and the second electrode 14 are arranged below the underlying substrate 11 in that order, and the touching finger shall be located above the ultrasonic sensing element 16, that is, the second electrode 14 are further to the finger than the first electrode 12, so the second electrode 14 can include a plurality of stacked sub-electrode layers, and the touching finger shall be located below the ultrasonic sensing element; and as illustrated in FIG. 2, the first electrode 12 is further to the finger than the second electrode 14, so the first electrode 12 can include a plurality of stacked sub-electrode layers, that is, the first electrode 12 includes a first sub-electrode layer 121 and a second sub-electrode layer 122 arranged successively. Each ultrasonic sensing element 16 can alternatively be arranged above the underlying substrate 11 as illustrated in FIG. 3, where the first electrode 2, the piezoelectric layer 13, and the second electrode 14 are arranged above the underlying substrate 11 in that order, and the touching finger shall be located above the ultrasonic sensing element 16, that is, the first electrode 12 are further to the finger than the second electrode 14, so the first electrode 12 can include a plurality of stacked sub-electrode layers, and the touching finger shall be located below the ultrasonic sensing element 16; and as illustrated in FIG. 4, the second electrode 14 is further to the finger than the first electrode 12, so the second electrode 14 can include a plurality of stacked sub-electrode layers.

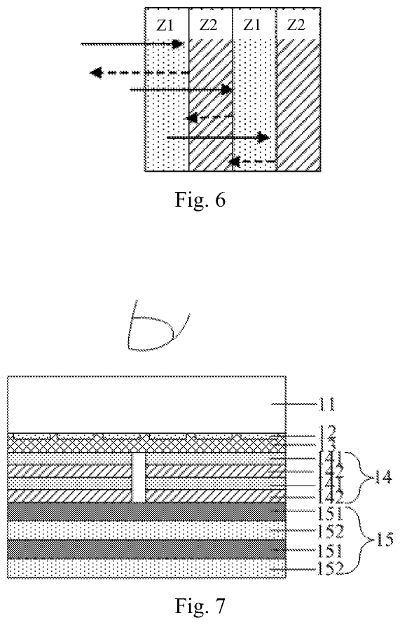

When the ultrasonic signal is propagated at the interface between the two layers with different sonic impedances, for a planar sound wave, a sonic impedance is equal to the product of a density and a velocity. Reflected energy of a normally incident planar sound wave is represented as Zs=ρ₀c₀, ρ₀ is the density of the layer, c₀ is the velocity of the ultrasonic signal at the layer. If there is a larger difference between their sonic impedances, then there will be a larger reflection coefficient, and more energy will be reflected; and as illustrated in FIG. 5, when the ultrasonic signal is transmitted from the layer I to the layer II, the reflected energy is represented as

$$r 1 = \frac{{\vert {p}_{r 0} \vert}^{2}}{2 {ρ}_{1} {c}_{1}} \text{/} \frac{{\vert {p}_{i 0} \vert}^{2}}{2 {ρ}_{1} {c}_{1}} = {( \frac{{ρ}_{2} {c}_{2} - {ρ}_{1} {c}_{1}}{{ρ}_{2} {c}_{2} + {ρ}_{1} {c}_{1}} )}^{2} ,$$

where r1 is the energy reflected when the ultrasonic signal is transmitted from the layer I to the layer II, pᵣ₀ is a sonic impedance of the ultrasonic signal at the layer I, pᵢ₀ is a sonic impedance of the ultrasonic signal at the layer II, ρ₁ is the density of the layer I, c₁ is the velocity of the ultrasonic signal at the layer I, ρ₂ is the density of the layer II, and c₂ is the velocity of the ultrasonic signal at the layer II. If a plurality of layers are structured in a stack, then as illustrated in FIG. 6, the ultrasonic signal can be reflected at a plurality of interfaces, where the reflected ultrasonic signal is represented as a dotted line, so that the efficiency of reflecting the ultrasonic signal can be improved to thereby make it less difficult to form a patterned ultrasonic reflecting electrode layer with a large thickness.

In a particular implementation, as illustrated in FIG. 7, the second electrodes 14 are sorted behind in the direction in which the ultrasonic signal is transmitted to the finger, so the fingerprint recognizing device can further include a protective layer 15 located on the sides of the second electrodes 14 away from the piezoelectric layer 13, where the protective layer 15 includes a plurality of stacked sub-protective layers, and there are different sonic impedances of two adjacent sub-protective layers; and for example, the protective layer 15 includes a first sub-protective layer 151 and a second sub-protective layer 152 stacked in that order, and there are different sonic impedances of the first sub-protective layer 151 and the second sub-protective layer 152. Stated otherwise, in a particular implementation, if the protective layer 15 is further arranged on the sides of the second electrodes 14 away from the piezoelectric layer 13 in the fingerprint recognizing device, and the protective layer 15 is also a layer arranged behind in the direction in which the ultrasonic signal is transmitted to the finger, then the protective layer 15 may also be structured as a plurality of stacked sub-protective layers so that the protective layer 15 can reflect the ultrasonic signal while protecting the second electrodes to thereby totally reflect the ultrasonic signal more effectively. The protective layer is generally an insulation layer, so that the materials of two adjacent sub-protective layers can be silicon nitride and resin respectively. Stated otherwise, particular components of the protective layer 15 can be silicon nitride, resin, silicon nitride, resin, silicon nitride, and resin, for example, the first sub-protective layer 151 is silicon nitride and a second sub-protective layer 152 is resin, and particularly two, three, four, five, or more sub-protective layers can be arranged. The plurality of stacked sub-protective layers may include sub-protective layers of only two different materials, which are stacked in order, or may include sub-protective layers of three, four, or more different materials, where there are two different sonic impedances of two adjacent sub-protective layers, and the plurality of sub-protective layers in the different materials are stacked in order.

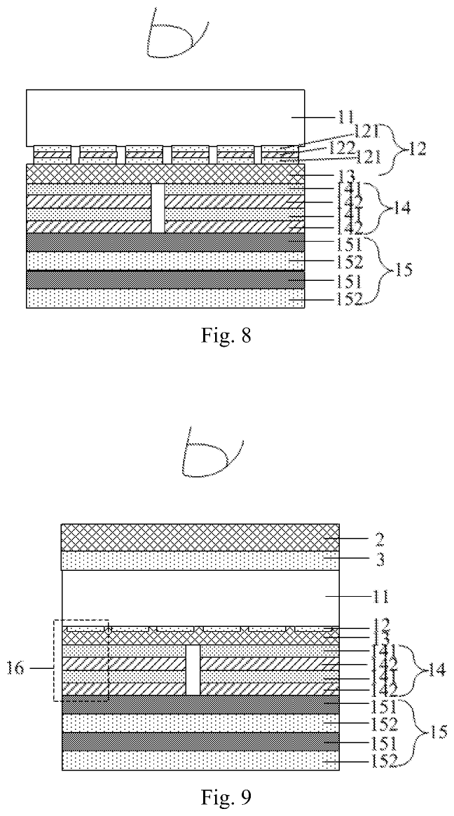

In a particular implementation, as illustrated in FIG. 8, alternatively the first electrode 12 and the second electrode 14 of each ultrasonic sensing element can be structured respectively in a stack, that is, one of the first electrode 12 and the second electrode 14, which is sorted ahead in the direction in which the ultrasonic signal is transmitted to the finger, also includes a plurality of stacked sub-electrode layers. In the embodiment of the disclosure, the first electrode 12 and the second electrode 14 are structured respectively as a plurality of stacked layers so that a reflection chamber is formed between the first electrode 12 and the second electrode 14, and an ultrasonic wave can be reflected repeatedly and superimposed onto each other in the reflection cavity to thereby further increase the energy of the sound wave.

However, when the first electrode 12 and the second electrode 14 are structured respectively in a stack, the ultrasonic signal to be reflected shall be reflected to the finger side, that is, the number of sub-electrode layers in one of the first electrode 12 and the second electrode 14, which is sorted behind in the direction in which the ultrasonic signal is transmitted to the finger (the second electrode 14 as illustrated in FIG. 8) is greater than the number of sub-electrode layers in the other one of them, which is sorted ahead (the first electrode 12 as illustrated in FIG. 8).

In a particular implementation, the first electrodes in embodiments of the disclosure can be one of receiving electrodes Rx and transmitting electrodes Tx, and the second electrodes can be the other of the receiving electrodes Rx and the transmitting electrodes Tx. However there is required high precision of the receiving electrodes, and the receiving electrodes can be formed in a similar process flow to the other circuit structures on the underlying substrate, e.g., a photolithograph process, so the receiving electrodes can be arranged closer to the underlying substrate, that is, in the embodiment of the disclosure, the first electrodes can be receiving electrodes, and the second electrodes can be transmitting electrodes. Since the receiving electrodes are configured to recognize a signal reflected back from a corresponding position of the finger, each receiving electrode can be shaped as a small square, the receiving electrodes of the respective ultrasonic sensing elements can be separate from each other, and the receiving electrodes of a plurality of fingerprint recognizing devices can be distributed in an array. In order to form the transmitting electrodes simply, the transmitting electrodes of all the ultrasonic sensing elements can be shaped as an integral planar electrode. However when the transmitting electrodes of all the ultrasonic sensing elements are formed as an integral planar electrode, a signal delay (e.g., an RC delay) may occur, thus possibly hindering the ultrasonic signal from being transmitted, so the transmitting electrodes as the integral planar electrode can be segmented, that is, a plurality of adjacent ultrasonic sensing elements are grouped together, the transmitting electrodes of the same group of ultrasonic sensing elements are formed as an integral planar electrode, and the transmitting electrodes of different groups of ultrasonic sensing elements are spaced from each other.

In a particular implementation, when each second electrode 14 includes a plurality of stacked sub-electrode layers, the materials of two adjacent sub-electrode layers of the second electrode 14 are molybdenum and aluminum respectively, for example, the first sub-protective layer 141 is molybdenum and the second sub-protective layer 142 is aluminum, and when each first electrode 12 includes a plurality of stacked sub-electrode layers, the materials of two adjacent sub-electrode layers of the first electrode 12 are tin indium oxide and aluminum respectively, for example, the first sub-protective layer 121 is tin indium oxide, and the second sub-protective layer 122 is aluminum.

Based upon the same inventive idea, some embodiments of the disclosure further provide a display device as illustrated in FIG. 9, which includes the fingerprint recognizing devices according to embodiments of the disclosure, and a display module 2.

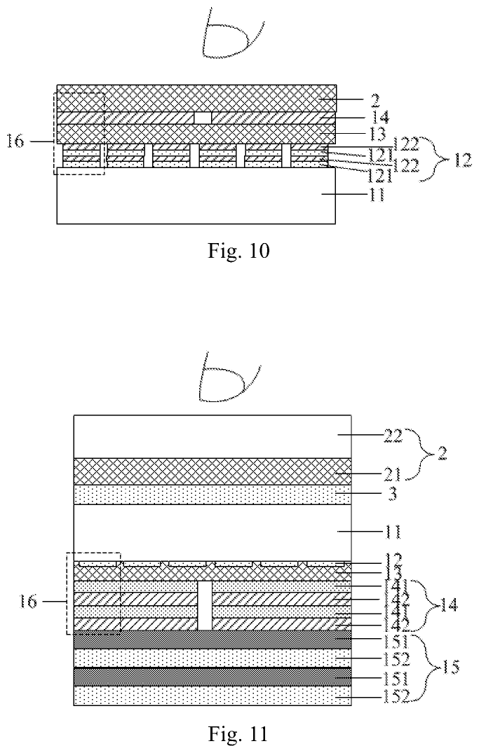

In a particular implementation, the display module 2 and the ultrasonic sensing elements 16 can be located respectively on different sides of the underlying substrate 11, and as illustrated in FIG. 9, for example, the display module 2 and the ultrasonic sensing elements 16 are located on different sides of the underlying substrate 11, and the display module 2 is fit on the underlying substrate 11 of the fingerprint recognizing devices through an adhesive layer 3, and at this time, if the side of the display module 2 away from the ultrasonic sensing elements 16 is a touch and display face, then the second electrodes 14 will be structured as a plurality of sub-electrode layers. Alternatively the display module 2 and the ultrasonic sensing elements 16 can be located respectively on the same side of the underlying substrate 11, and as illustrated in FIG. 10, for example, both of them are located above the underlying substrate 11; and when the display module 2 and the ultrasonic sensing elements 16 are located on the same side of the underlying substrate 11, and the ultrasonic sensing elements 16 are located between the display module 2 and the underlying substrate 11, and at this time, if the side of the display module 2 away from the ultrasonic sensing elements 16 is a touch and display face, then the first electrodes 12 will be structured as a plurality of sub-electrode layers.

In a particular implementation, when the side of the display module away from the fingerprint recognizing devices is a touch face, and the first electrodes and the second electrodes of the fingerprint recognizing devices include a plurality of stacked sub-electrode layers respectively, the number of sub-electrode layers in one of the first electrodes and the second electrodes, which are away from the display module is greater than the number of sub-electrode layers in the other of them, so that a generated ultrasonic signal is propagated to the touch face.

In a possible implementation, as illustrated in FIG. 11, the display module 2 includes a light-emitting diode device 21, and an encapsulation cover plate 22 located on the side of the light-emitting diode element 21 away from the ultrasonic sensing elements 16, where the light-emitting diode device 21 can include Organic Light-Emitting Diode (OLED) elements, and the light-emitting diode device 21 can include a plurality of light-emitting diode elements, and a light-emission driving backboard configured to drive the light-emitting diode elements to emit light. Of course, the underlying substrate 11 of the fingerprint recognizing devices can further include a driving circuit configured to drive the ultrasonic sensing elements to operate.

In a possible implementation, the first electrodes and the second electrodes of the fingerprint recognizing devices are reused as touch electrodes. Fingerprint recognition and a touch can be performed in a time division manner.

A fingerprint recognition principle of the display device according to embodiments of the disclosure will be described below as follows by way of an example in which the fingerprint recognizing devices are integrated in the display device, the first electrodes are receiving electrodes, and the second electrodes are transmitting electrodes.

In order to perform fingerprint recognition, ultrasonic signals are transmitted in such a way that a fixed potential (e.g., zero voltage) is applied to the first electrodes Rx of all the ultrasonic sensing elements, and alternating voltage (e.g., ±5V voltage) is applied to the second electrodes Tx of all the ultrasonic sensing elements, so that the piezoelectric layer is deformed (or the piezoelectric layer material brings an adjacent layer into vibration), where some generated ultrasonic signals are propagated directly to the finger, and some generated ultrasonic signals are propagated in the opposite direction; and when the ultrasonic signals propagated in the opposite direction encounter the first or second electrodes including a plurality of sub-electrode layers, the generated ultrasonic signals are propagated to the finger so that they can be transmitted to the outside as many as possible. Ultrasonic signals are received in such a way that a fixed potential is applied to the second electrodes Tx of all the ultrasonic sensing elements, and the first electrodes Rx of all the ultrasonic sensing element receive the ultrasonic signals reflected back by the finger respectively, that is, when the ultrasonic signals reflected back by the finger are reflected to the piezoelectric layer, they are converted into AC voltage, and the first electrodes Rx receive the output signals. Since valleys and ridges of the finger reflect different energies, the signals which are reflected back are different, so that fingerprint recognition is performed.

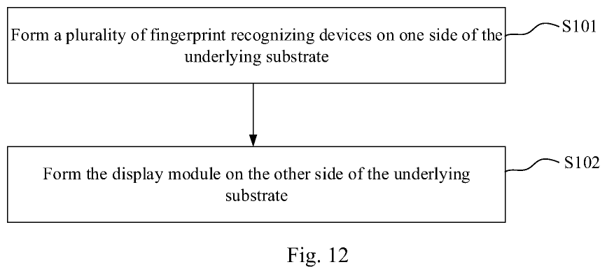

Some embodiments of the disclosure further provide a method for fabricating the display device, and as illustrated in FIG. 12, the method includes the following steps:

the step S101 is to form a plurality of fingerprint recognizing devices on one side of the underlying substrate; and

the step S102 is to form the display module on the other side of the underlying substrate.

Here forming the plurality of fingerprint recognizing devices on one side of the underlying substrate includes:

forming the plurality of stacked sub-electrode layers in order, where there are different sonic impedances of two adjacent sub-electrode layers, where one of the first electrodes and the second electrodes including the plurality of stacked sub-electrode layers in the fingerprint recognizing devices are sorted behind in the direction in which an ultrasonic signal is transmitted to the finger.

Advantageous effects of the embodiments of the disclosure are as follows: the fingerprint recognizing device according to the embodiment of the disclosure includes a plurality of ultrasonic sensing elements located on one side of an underlying substrate, each of which includes a first electrode, a piezoelectric layer located on the side of the first electrode away from the underlying substrate, and a second electrode located on the side of the piezoelectric layer away from the first electrode, where one of the first electrode and the second electrode, which is sorted behind in the direction in which an ultrasonic signal is transmitted to a finger, includes a plurality of stacked sub-electrode layers, and there are different sonic impedances of two adjacent sub-electrode layers, that is, the first electrode or the second electrode sorted behind is structured as a plurality of stacked sub-electrode layers, and since there are different sonic impedances of two adjacent sub-electrode layers, and an ultrasonic signal is reflected between interfaces of the two layers with different sonic impedances, the plurality of stacked layers with different sonic impedances can reflect the generated ultrasonic signal to the finger side to thereby improve the intensity of the emitted ultrasonic signal so as to detect a fingerprint, thus avoiding such a problem that when a patterned ultrasonic reflecting electrode layer with a large thickness is formed in a screen-printing process, the pattern may be less refined, and when the ultrasonic reflecting layer is formed in a photolithograph process, a demand for ultrasonic reflection may be difficult to satisfy due to the thickness of the ultrasonic reflecting layer.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. A fingerprint recognizing device, comprising a plurality of ultrasonic sensing elements, wherein the plurality of ultrasonic sensing elements comprise a first electrode, a piezoelectric layer located on one side of the first electrode, and a second electrode located on a side of the piezoelectric layer away from the first electrode, wherein:
at least one of the first electrode and the second electrode comprises a plurality of stacked sub-electrode layers, and two adjacent sub-electrode layers have different sonic impedances.

2. The fingerprint recognizing device according to claim 1, wherein the second electrodes comprise a plurality of stacked sub-electrode layers; and
the fingerprint recognizing device further comprises a protective layer located on a side of the second electrode away from the piezoelectric layer, the protective layer comprises a plurality of stacked sub-protective layers, and two adjacent sub-protective layers have different sonic impedances.

3. The fingerprint recognizing device according to claim 2, wherein materials of the two adjacent sub-protective layers are silicon nitride and resin respectively.

4. The fingerprint recognizing device according to claim 2, wherein materials of the two adjacent sub-electrode layers of the second electrode are molybdenum and aluminum respectively.

5. The fingerprint recognizing device according to claim 1, wherein the first electrode and the second electrode comprise a plurality of stacked sub-electrode layers respectively.

6. The fingerprint recognizing device according to claim 1, wherein the first electrode is a receiving electrode, and the second electrode is a transmitting electrode.

7. The fingerprint recognizing device according to claim 6, wherein a plurality of adjacent ultrasonic sensing elements are grouped together, transmitting electrodes of a group of ultrasonic sensing elements are formed as an integral planar electrode, and the transmitting electrodes of different groups of ultrasonic sensing elements are spaced from each other.

8. A display device, comprising the fingerprint recognizing device according to claim 1, and a display module.

9. The display device according to claim 8, wherein the fingerprint recognizing devices comprise an underlying substrate on which the plurality of ultrasonic sensing elements are arranged, the display module and the ultrasonic sensing elements are located on different sides of the underlying substrate, and the display module is fit on the underlying substrate of the fingerprint recognizing devices through an adhesive layer.

10. The display device according to claim 8, wherein the fingerprint recognizing devices comprise an underlying substrate on which the plurality of ultrasonic sensing elements are arranged, the display module and the ultrasonic sensing elements are located on a same side of the underlying substrate, and the ultrasonic sensing elements are located between the display module and the underlying substrate.

11. The display device according to claim 9, wherein the first electrode and the second electrode comprise a plurality of stacked sub-electrode layers respectively, and a quantity of sub-electrode layers in one of the first electrode and the second electrode, is greater than a quantity of sub-electrode layers in the other one of the first electrode the second electrode, wherein the one of the first electrode and the second electrode is away from the display module.

12. The display device according to claim 10, wherein the first electrode and the second electrode comprise a plurality of stacked sub-electrode layers respectively, and a quantity of sub-electrode layers in one of the first electrode and the second electrode is greater than a quantity of sub-electrode layers in the other one of the first electrode the second electrode, wherein the one of the first electrode and the second electrode is away from the display module.

13. The display device according to claim 9, wherein the display module comprises a light-emitting diode device, and an encapsulation cover plate located on a side of the light-emitting diode element away from the ultrasonic sensing elements.

14. The display device according to claim 10, wherein the display module comprises a light-emitting diode device, and an encapsulation cover plate located on a side of the light-emitting diode element away from the ultrasonic sensing elements.

15. The display device according to claim 8, wherein the first electrode and the second electrode of the fingerprint recognizing devices are reused as touch electrodes.
